(19) United States
(12) Patent Application Publication
(10) Pub. No.: US 2024/0175924 A1
(43) Pub. Date: May 30, 2024

(54) BATTERY MONITORING CIRCUITS

(71) Applicant: O2Micro Inc., Santa Clara, CA (US)

(72) Inventors: Guoxing LI, Sunnyvale, CA (US); Yan LI, Wuhan (CN)

(21) Appl. No.: 18/072,386

(22) Filed: Nov. 30, 2022

(51) Int. Cl. G01R 31/364; H02J 7/00

(52) U.S. Cl. CPC G01R 31/364; H02J 7/0047

(57) ABSTRACT

In a battery monitoring circuit, a bypath circuit includes a first terminal coupled to a positive terminal of a battery cell and a second terminal coupled to a negative terminal of the battery cell. A resistive component includes a third terminal coupled to the second terminal of the bypath circuit, and includes a fourth terminal coupled to a reference signal source that controls the resistive component to generate a reference voltage. A controller controls turning on and off the bypath circuit and the reference signal source, monitors a status of the battery cell when the bypath circuit and the reference signal source are off, senses a test voltage between the first terminal and the fourth terminal when the bypath circuit and the reference signal source are on, and generates a status signal indicative of an operating status of the battery monitoring circuit according to the test voltage.

### BACKGROUND

FIG. 1 illustrates a circuit diagram of a conventional battery pack 100. As shown in FIG. 1, the battery pack 100 includes battery cells 120A, 120B, 120C, etc., and a battery monitoring circuit 110. The battery monitoring circuit 110 includes bypath circuits 112A, 112B, 112C, etc., and a battery monitor 114. Each battery cell is coupled to a bypath circuit through a set of resistors and connection terminals. For example, the positive terminal of the battery cell 120A is coupled to the first terminal 116 of the bypath circuit 112A through the resistor R_{FN} and the connection terminal VB_{N}, and the negative terminal of the battery cell 120A is coupled to the second terminal 118 of the bypath circuit 112A through the resistor R_{F(N-1)} and the connection terminal VB_{(N-1)}. The bypath circuits are used to balance the battery voltages of the battery cells. For example, the bypath circuit 112A can discharge the battery cell 120A if the bypath circuit 112A is on, so that the voltage of the battery 120A is close to or the same as the voltages of the other battery cells. The battery monitor 114 includes multiple level shifters (e.g., including a level shifter 114-1, and other similar level shifters not shown in FIG. 1). Each level shifter is coupled to a bypath circuit. For example, the level shifter 114-1 is coupled to the bypath circuit 112A. The battery monitor 114 senses a voltage of a battery cell through a level shifter. For example, the battery monitor 114 can sense the voltage of the battery cell 120A through the level shifter 114-1. Accordingly, the battery monitor 114 can monitor statuses of the battery cells 120A, 120B, 120C, etc., by using the level shifters to sense battery voltages of the battery cells.

However, when the battery monitor 114 senses the voltage of the battery cell 120A through the level shifter 114-1, the level shifter 114-1 draws a current I_{RFN} from the positive terminal of the battery cell 120A but does not draw a current from the negative terminal of the battery cell 120A. The current I_{RFN} from the positive terminal of the battery cell 120A flows through the resistor R_{FN} and causes a voltage drop across the resistor R_{FN}. The voltage drop across the resistor R_{FN} leads to the voltage of the battery cell 120A being inaccurately sensed by the battery monitor 114. Similarly, when sensing voltages of the battery cells 120B, 120C, etc., the battery monitor 114 may not be able to get accurate information for the voltages of the battery cells 120B, 120C, etc.

In addition, as the battery cells discharge, the voltages of the battery cells will decrease. Because the battery monitor 114 has a minimum input voltage (e.g., 0.8V, 0.9V, or 1V), the battery monitor 114 cannot sense a voltage of a battery cell if the voltage of the battery cell is less than the minimum input voltage. Moreover, in the assembly process of the battery pack 100, there may be cases where one battery cell of the battery cells is reversely coupled to the other battery cells. The battery monitor 114 cannot sense the voltage of the battery cell that is reversely coupled to the other battery cells. Furthermore, during the production or operation of the battery pack 100, various circuit faults may occur in the battery pack 100. For example, there may be an open circuit in the battery monitoring circuit 110, or the battery monitoring circuit 110 may be disconnected from the battery cells. However, the battery monitor 114 cannot detect these circuit failures.

### SUMMARY

In an embodiment, a battery monitoring circuit includes a bypath circuit, a resistive component, a reference signal source, and a controller coupled to the bypath circuit, the resistive component, and the reference signal source. The bypath circuit includes a first terminal coupled to a positive terminal of a battery cell, and includes a second terminal coupled to a negative terminal of the battery cell. The resistive component includes a third terminal and a fourth terminal. The third terminal is coupled to the second terminal. The reference signal source is coupled to the fourth terminal, and is configured to provide a reference signal to the resistive component to cause the resistive component to generate a reference voltage. The controller is configured to control turning on and off the bypath circuit and the reference signal source, and is also configured to monitor a status of the battery cell when the bypath circuit and the reference signal source are off. The controller is configured to sense a first test voltage between the first terminal and the fourth terminal when the bypath circuit and the reference signal source are on, and is further configured to generate a status signal indicative of an operating status of the battery monitoring circuit according to the first test voltage.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIG. 1 illustrates a circuit of a conventional battery pack.

FIG. 2A illustrates a circuit of an example of a battery pack, in an embodiment of the present invention.

FIG. 2B illustrates a circuit of an example of a battery pack, in an embodiment of the present invention.

FIG. 3A illustrates a circuit of an example of a battery pack, in an embodiment of the present invention.

FIG. 3B illustrates a circuit of an example of a battery pack, in an embodiment of the present invention.

FIG. 4A illustrates a circuit of an example of a battery pack, in an embodiment of the present invention.

FIG. 4B illustrates a circuit of an example of a battery pack, in an embodiment of the present invention.

FIG. 5 illustrates a flowchart of an example of a method for monitoring a battery, in an embodiment of the present invention.

### DETAILED DESCRIPTION

Reference will now be made in detail to the embodiments of the present invention. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Embodiments according to the present invention provide a battery pack that includes multiple battery cells and a battery monitoring circuit, and provide a method for monitoring the battery cells. The battery monitoring circuit includes multiple bypath circuits, multiple resistive components, a reference signal source, and a controller. By using the bypath circuits, resistive components, and reference signal source, the controller can get more accurate information for the voltages of the battery cells, can sense a cell voltage of a battery cell if that cell voltage is less than the minimum input voltage of the controller, and can sense a voltage of a battery cell if that battery cell is reversely coupled to the other battery cells. Additionally, the battery monitoring circuit can perform a self-test function by controlling the bypath circuits and reference signal source, thereby detecting circuit failures.

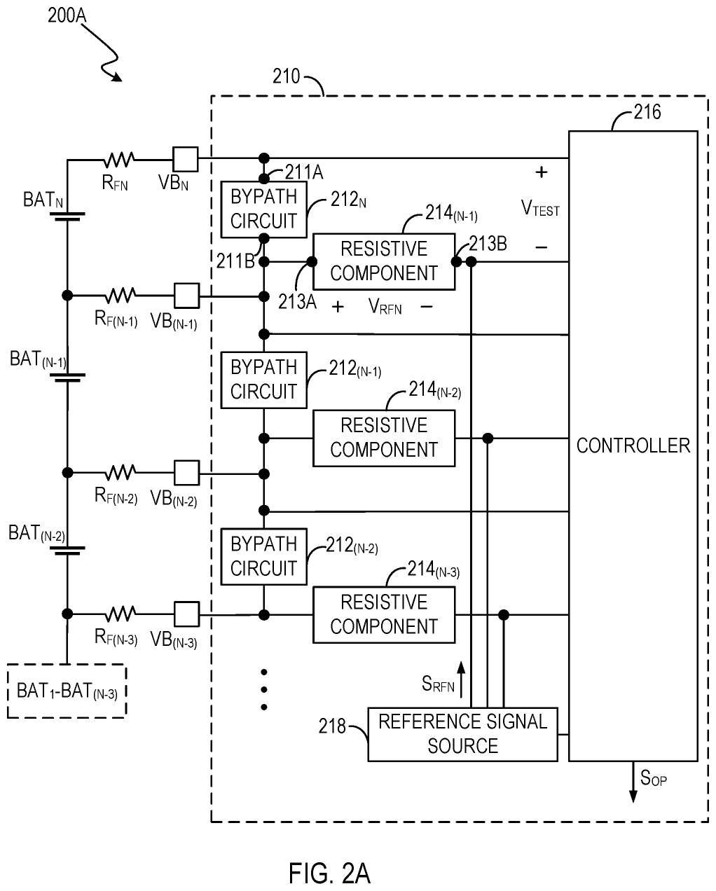

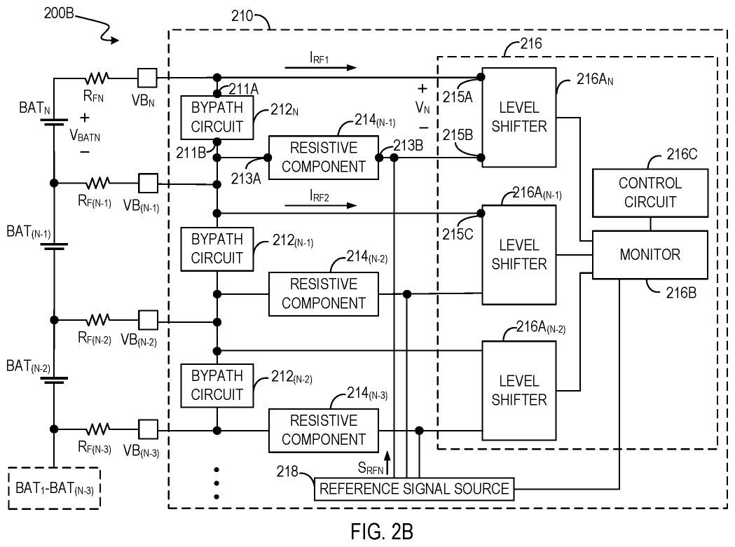

FIG. 2A illustrates a circuit diagram of an example of a battery pack 200A, in an embodiment of the present invention. As shown in FIG. 2A, the battery pack 200A includes multiple battery cells BAT₁-BAT_{N} and a battery monitoring circuit 210 that monitors statuses of the battery cells BAT₁-BAT_{N}. In an embodiment, the battery cells BAT₁-BAT_{N} are rechargeable battery cells. For example, the battery cells BAT₁-BAT_{N} can include lithium-ion (Li-ion) battery cells. For another example, the battery cells BAT₁-BAT_{N} may include lead-acid battery cells, nickel-cadmium (NiCd) battery cells, nickel-metal hydride (NiMH) battery cells, or the like. The battery monitoring circuit 210 includes multiple bypath circuits (e.g., including bypath circuits 212_{N}, 212_{(N-1)} and 212_{(N-2)}, and additional bypath circuits not shown in FIG. 2A), and multiple resistive components (e.g., including resistive components 214_{(N-1)}, 214_{(N-2)} and 214_{(N-3)}, and additional resistive components not shown in FIG. 2A). The battery monitoring circuit 210 also includes a reference signal source 218 and a controller 216. As used herein, N represents a natural number greater than one.

In an embodiment, each bypath circuit 212₁-212_{N} includes circuits used to implement the on-off function. In an embodiment, a bypath circuit 212_{K} (K=1, 2, . . . , N) includes a balance circuit that can balance a voltage of a corresponding battery cell BAT_{K} with voltages of the other battery cells. More specifically, the bypath circuit 212_{K} can include a switch in series with a resistor. The bypath circuit 212_{K} can be controlled by the controller 216. Each resistive component 214₁-214_{(N-1)} can include one or more resistors. The reference signal source 218 can include circuitry for outputting a reference signal S_{RFN}.

As shown in FIG. 2A, the bypath circuit 212_{K} is coupled to a corresponding battery cell BAT_{K}. More specifically, the bypath circuit 212_{K} includes a first terminal coupled to a positive terminal of the corresponding battery cell BAT_{K}, and a second terminal coupled to a negative terminal of the corresponding battery cell BAT_{K}. For example, the bypath circuit 212_{N} includes a first terminal 211A and a second terminal 211B. The positive terminal of the battery cell BAT_{N} is coupled to the first terminal 211A through a resistor R_{FN} and a connection terminal VB_{N}, and the negative terminal of the battery cell BAT_{N} is coupled to the second terminal 211B through a resistor R_{F(N-1)} and a connection terminal VB_{(N-1)}. Similarly, a resistive component 214_{(K-1)} is coupled to a corresponding bypath circuit 212_{K}, and includes a third terminal and a fourth terminal. The third terminal of the resistive component 214_{(K-1)} is coupled to the second terminal of the corresponding bypath circuit 212_{K}. For example, the resistive component 214_{(N-1)} includes a third terminal 213A and a fourth terminal 213B. The third terminal 213A is coupled to the second terminal 211B of the bypath circuit 212_{N}. The reference signal source 218 is coupled to the fourth terminal of each resistive component 214₁-214_{(N-1)}, and is configured to provide a reference signal S_{RFN} to a selected resistive component of the resistive components 214₁-214(N−1) to cause the selected resistive component to generate a reference voltage V_{RFN}. For example, if the resistive component 214_{(N-1)} is the selected resistive component, then the reference signal source 218 can provide a reference signal SUN (e.g., a current signal) to the resistive component 214_{(N-1)} to cause the resistive component 214_{(N-1)} to generate a reference voltage V_{RFN}.

In an embodiment, the battery monitoring circuit 210 can sense the battery cells BAT₁-BAT_{N} one by one in an order. In other words, the battery monitoring circuit 210 can select one battery cell among the battery cells BAT₁-BAT_{N} one by one and sense it. The battery cell selected by the battery monitoring circuit 210 can be referred to as a selected battery cell. The bypass circuit and the resistive component corresponding to the selected battery cell can be referred to as the selected bypass circuit and the selected resistive component, respectively.

In an embodiment, the controller 216 includes circuitry for implementing controlling and sensing functions. More specifically, the controller 216 can control turning on and off the bypath circuits 212₁-212_{N} and the reference signal source 218. For example, the controller 216 can turn on the bypath circuit 212_{N} so that a current can be conducted between the first terminal 211A and the second terminal 2111B. The controller 216 can turn on the reference signal source 218 to cause the resistive component 214_{(N-1)} to generate a reference voltage V_{RFN}. In addition, the controller 216 can monitor a status of a selected battery cell of the battery cells BAT₁-BAT_{N} when a selected bypath circuit of the bypath circuits 212₁-212_{N}, coupled to the selected battery cell, is off, and the reference signal source 218 is also off. For example, if the battery cell BAT_{N} is the selected battery cell and the bypath circuit 212_{N} is the selected bypath circuit, then the controller 216 can sense a voltage (e.g., a voltage V_{TEST1} shown in FIG. 2A) of the battery cell BAT_{N} through the first terminal 211A and the fourth terminal 213B, when the bypath circuit 212_{N} and the reference signal source 218 are off.

In an embodiment, the controller 216 can sense a test voltage (e.g., a first test voltage V_{TEST1}, a second test voltage V_{TEST2}, or a third test voltage V_{TEST3} as described below) between the first terminal of the selected bypath circuit and the fourth terminal of the selected resistive component, where the selected resistive component is coupled to the selected bypath circuit. The controller 216 can further generate a status signal Sop indicative of an operating status of the battery monitoring circuit 210 according to the test voltage. Examples of the first test voltage V_{TEST1}, the second test voltage V_{TEST2}, and the third test voltage V_{TEST3} are described below with reference to FIG. 2A.

In an embodiment, the controller 216 can sense a first test voltage V_{TEST1} between the first terminal of the selected bypath circuit and the fourth terminal of the selected resistive component when the selected bypath circuit and the reference signal source 218 are on, where the selected resistive component is coupled to the selected bypath circuit. The controller 216 can further generate a status signal Sop indicative of an operating status of the battery monitoring circuit 210 according to the first test voltage V_{TEST1}. By way of example, if the bypath circuit 212_{N} is the selected bypath circuit and the resistive component 214_{(N-1)} is the selected resistive component, then when the bypath circuit 212_{N} and the reference signal source 218 are on, a voltage between the first terminal 211A and the fourth terminal 213B (e.g., referred to as a first test voltage V_{TEST1}) will be close to the reference voltage V_{RFN} if the controller 216, the bypath circuit 212_{N}, and the resistive component 214_{(N-1)} are normal. If an abnormal condition is present in the bypath circuit 212_{N} or the resistive component 214_{(N-1)}—for example, if there is an open circuit in the bypath circuit 212_{N} or the resistive component 214_{(N-1)}—then the voltage between the terminals 211A and 213B may be equal to or approximately equal to 0V. In other words, the controller 216 can determine whether an abnormal condition is present in the battery monitoring circuit 210 according to the first test voltage V_{TEST1}, so that the controller 216 can generate a status signal Sop indicating an operating status of the battery monitoring circuit 210.

In an embodiment, the status signal Sop includes a monitoring circuit fault signal indicative of a fault in the battery monitoring circuit 210. The controller 216 can generate the monitoring circuit fault signal Sop if the first test voltage V_{TEST1} is outside a safe range, wherein the safe range is determined by the reference voltage V_{RFN} generated by the selected resistive component. For example, the minimum value of the safe range can be 90% of the reference voltage V_{RFN}, and the maximum value of the safety range can be 110% of the reference voltage V_{RFN}. That is to say, (90%*V_{RFN}, 110%*V_{RFN}) can be considered as the safe range. In an embodiment, if the reference voltage V_{RFN} generated by the resistive component 214_{(N-1)} is 2V, then the safe range is 1.8V to 2.2V. The controller 216 senses the first test voltage V_{TEST1}. If the first test voltage V_{TEST1} is 2.1V for example—that is, the first test voltage V_{TEST1} is within the safe range—then the controller 216 can determine that the battery monitoring circuit 210 is normal, and can generate an indication signal Sop indicating that the battery monitoring circuit 210 is operating normally. If the first test voltage V_{TEST1} is 0V for example—that is, the first test voltage V_{TEST1} is outside the safe range—then the controller 216 can determine that an abnormal condition, e.g., an open circuit, is present in the battery monitoring circuit 210. Thus, a monitoring circuit fault signal Sop can be generated by the controller 216 to indicate a fault in the battery monitoring circuit 210.

In an embodiment, the status signal Sop also includes a battery fault signal indicative of a fault in the battery cells BAT₁-BAT_{N}. The controller 216 can sense a second test voltage V_{TEST2} between the first terminal of the selected bypath circuit and the fourth terminal of the selected resistive component when the selected bypath circuit is on and the reference signal source 218 is off. The controller 216 can further sense a third test voltage V_{TEST3} between the first terminal of the selected bypath circuit and the fourth terminal of the selected resistive component when the selected bypath circuit and the reference signal source 218 are off. The controller 216 can generate the battery fault signal Sop if the second test voltage V_{TEST2} and the third test voltage V_{TEST3} are less than a preset level V_{PL}. The preset level V_{PL} can include a relatively low voltage level such as 0V, 0.1V, 0.2V, or the like. To illustrate, consider an example in which the bypath circuit 212_{N} is the selected bypath circuit, the resistive component 214_{(N-1)} is the selected resistive component, and the preset level V_{PL} is 0.1V. The controller 216 senses the second test voltage V_{TEST2} and the third test voltage V_{TEST3}. In this example, if the second test voltage V_{TEST2} is 0V and the third test voltage V_{TEST3} is 4.1V—that is, the second test voltage V_{TEST2} is less than the preset level V_{PL} and the third test voltage V_{TEST3} is greater than the preset level—then the controller 216 can determine that the battery cell BAT_{N} is normal, and can generate an indication signal, e.g., Sop, indicating that the battery cell BAT_{N} is operating normally. In this example, if the second test voltage V_{TEST2} is 0V and the third test voltage V_{TEST3} is 0V—that is, the second test voltage V_{TEST2} and the third test voltage V_{TEST3} are less than the preset level V_{PL} —then the controller 216 can determine that an abnormal condition, e.g., a loose connection, is present in the battery cell BAT_{N}. Thus, a battery fault signal Sop can be generated by the controller 216 to indicate a fault in the battery cells BAT₁-BAT_{N}.

In an embodiment, the controller 216 can sense a second test voltage V_{TEST2} between the first terminal of the selected bypath circuit and the fourth terminal of the selected resistive component when the selected bypath circuit is off and the reference signal source 218 is on. The controller 216 can further determine a voltage V_{CELL} of the selected battery cell according to a difference between the second test voltage V_{TEST2} and the reference voltage V_{RFN} generated by the selected resistive component if the voltage V_{CELL} is less than a preset value V_{PV}. In an embodiment, the preset value V_{PV} is determined by a minimum input voltage V_{MIN} of the controller 216. For example, the preset value V_{PV} can be equal to the minimum input voltage V_{MIN}. For another example, the preset value V_{PV} can be equal to a sum of the minimum input voltage V_{MIN} and an increment (e.g., 0V, 0.1V, 0.2V, or the like).

More specifically, the controller 216 can determine the voltage V_{CELL} of the selected battery cell according to an equation V_{CELL}=V_{TEST2}-V_{RFN} if the voltage V_{CELL} is less than the preset value V_{PV}. To illustrate, consider an example in which the bypath circuit 212_{N} is the selected bypath circuit, the resistive component 214_{(N-1)} is the selected resistive component, and the preset value V_{PV} is 1.0V. In the process of sensing a voltage V_{CELL} of the battery cell BAT_{N}, the controller 216 can sense the cell voltage V_{CELL} when the bypath circuit 212_{N} and the reference signal source 218 are off. In this example, if the cell voltage V_{CELL} is less than 1.0V—that is, the voltage V_{CELL} is less than the preset value V_{PV}—then the controller 216 can turn off the bypath circuit 212_{N}, turn on the reference signal source 218, and sense the second test voltage V_{TEST2} between the first terminal 211A and the fourth terminal 213B. The controller 216 can determine the voltage V_{CELL} of the battery cell BAT_{N} according to a difference between the second test voltage V_{TEST2} and the reference voltage V_{RFN} generated by the resistive component 214_{(N-1)}. For example, the cell voltage V_{CELL} can be given by: V_{CELL}=V_{TEST2}-V_{RFN}. Thus, the second test voltage V_{TEST2} is a sum of the cell voltage V_{CELL} and the reference voltage V_{RFN}. In an embodiment, the reference voltage V_{RFN} can be set to be equal to or greater than the minimum input voltage V_{MIN} of the controller 216. As a result, even if the voltage V_{CELL} of the battery cell BAT_{N} is less than the minimum input voltage V_{MIN}, the second test voltage V_{TEST2} can be greater than the minimum input voltage V_{MIN}, so that the controller 216 can still sense the voltage of the battery cell BAT_{N}. In addition, in an embodiment, the reference signal source 218 can adjust the reference voltage V_{RFN} by adjusting the reference signal S_{RFN}. If the voltage of the battery cell BAT_{N} is negative (e.g., the battery cell BAT_{N} is reversely coupled to the battery cells BAT₁-BAT_{(N-1)}), then the reference signal S_{RFN} can be adjusted such that the second test voltage V_{TEST2} is greater than the minimum input voltage V_{MIN}. As a result, the controller 216 can still sense the voltage of the battery cell BAT_{N} even if the battery cell BAT_{N} is coupled to the battery monitoring circuit 210 in a wrong direction, e.g., reversely coupled to the other battery cells.

FIG. 2B illustrates a circuit diagram of an example of a battery pack 200B, in an embodiment of the present invention. FIG. 2B is described in combination with FIG. 2A. As shown in FIG. 2B, the controller 216 includes multiple level shifters (e.g., level shifters 216A_{N}, 216A_{(N-1)} and 216A_{(N-2)}, and additional level shifters not shown in FIG. 2B), a monitor 216B, and a control circuit 216C. A level shifter 216A_{L} (L=2, 3, . . . , N) is coupled to a battery cell BATL. More specifically, a level shifter 216A_{L} of the level shifters (e.g., referred to as a first level shifter) includes a first monitoring terminal and a second monitoring terminal. The first monitoring terminal is coupled to the positive terminal of the battery cell BAT_{L} through a first resistive component (e.g., a resistor R_{FL}), and the second monitoring terminal is coupled to the negative terminal of the battery cell BAT_{L} through a second resistive component (e.g., a resistor R_{F(L-1)}).

In an embodiment, the abovementioned level shifter, e.g., the level shifter 216A_{N} shown in FIG. 2B, can be referred to as a voltage level translator. The level shifter 216A_{N} can include a circuit used to translate a signal from one voltage domain to another, allowing compatibility between circuits with different voltage requirements. For example, the monitor 216B can monitor signals, e.g., voltage signals, that are referenced to ground, but by itself may not be able to recognize other signals, e.g., including a voltage V_{N} shown in FIG. 2B, that are not referenced to ground. The level shifter 216A_{N} can shift the voltage V_{N} to another signal level that the monitor 216B can recognize.

In an embodiment, the controller 216 can sense a voltage of a battery cell through a level shifter. For example, the control circuit 216C can turn on the level shifter 216A_{N} when used to sense the voltage of the battery cell BAT_{N}. After being turned on, the level shifter 216A_{N} can sense a first voltage signal V_{N} produced by the battery cell BAT_{N}. The first voltage signal V_{N} can indicate the voltage of the battery cell BAT_{N}. The level shifter 216A_{N} can further translate the first voltage signal V_{N} to a second voltage signal, and provide the second voltage signal to the monitor 216B. The monitor 216B can determine the voltage of the battery cell BAT_{N} according to the second voltage signal.

In addition, the controller 216 includes a compensation circuit. The compensation circuit is coupled to the negative terminal of the battery cell BAT_{L} through the second resistive component. In an embodiment, the compensation circuit can include the circuit adjacent to and coupled to the level shifter 216A_{L}. The compensation circuit can further draw a second current from the battery cell BAT_{L} through the second resistive component. More specifically, the compensation circuit includes a level shifter 216A_{(L-1)} (e.g., referred to as a second level shifter) adjacent to the level shifter 216A_{L}. The second level shifter 216A_{(L-1)} can sense a voltage of an adjacent battery cell BAT_{(L-1)} coupled in series to the battery cell BAT_{L} by receiving a current from the adjacent battery cell BAT_{(L-1)} through the second resistive component.

To illustrate, consider an example in which the level shifter 216A_{N} is the first level shifter, the battery cell BAT_{N} is the selected battery cell, and the level shifter 216A_{(N-1)} is the compensation circuit. The level shifter 216A_{N} includes a first monitoring terminal 215A and a second monitoring terminal 215B. The first monitoring terminal 215A is coupled to the positive terminal of the battery cell BAT_{N} through a resistor R_{FN}. The second monitoring terminal 215B is coupled to the negative terminal of the battery cell BAT_{N} through a resistor R_{F(N-1)} and, e.g., the resistive component 214_{(N-1)}. The level shifter 216A_{N}−1 is coupled to the negative terminal of the battery cell BAT_{N} through the resistor R_{F(N-1)}. In other words, a level shifter 216A_{(L-1)} can function as a compensation circuit for its adjacent level shifter 216A_{L} if the level shifter 216A_{(L-1)} is coupled with its adjacent level shifter 216A_{L} via the first monitoring terminal of the level shifter 216A_{(L-1)}. For example, the level shifter 216A_{(N-1)} can function as a compensation circuit for the level shifter 216A_{N}, the level shifter 216A_{(N-2)} can function as a compensation circuit for the level shifter 216A_{(N-1)}, etc.

In an embodiment, the first level shifter 216A_{L} (L=2, 3, . . . , N) can sense a voltage of the battery cell BAT_{L} by receiving a first current from the battery cell BAT_{L} through the first resistive component R_{FL}. The level shifter 216A_{(L-1)}, also refer to the compensation circuit, can draw a second current from the battery cell BAT_{L} through the second resistive component R_{F(L-1)}.

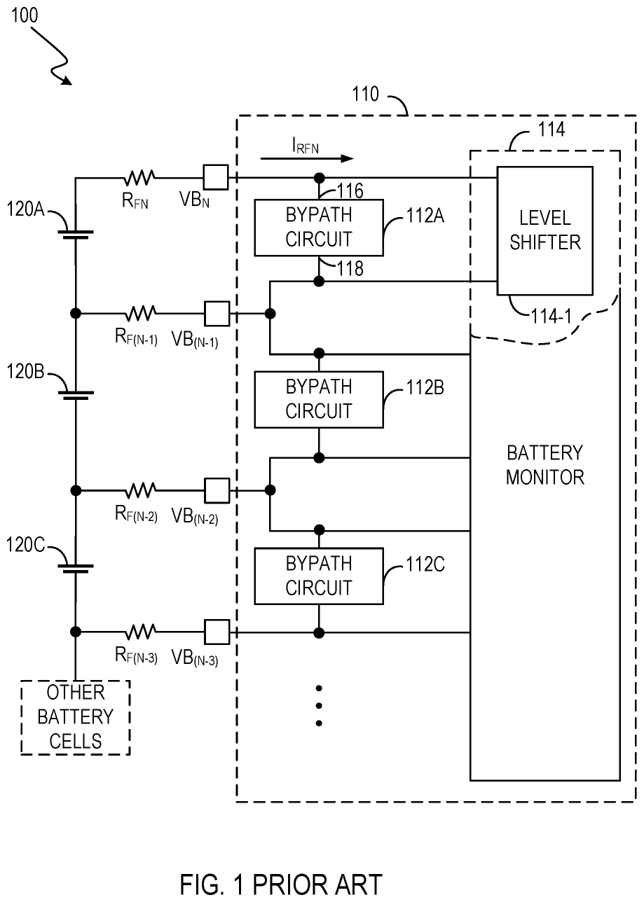

To illustrate, consider an example in which the level shifter 216A_{N} is the first level shifter, the battery cell BAT_{N} is the selected battery cell, and the level shifter 216A_{(N-1)} is the compensation circuit. The level shifter 216A_{N} can sense the voltage of the battery cell BAT_{N} by receiving a first current I_{RF1} from the battery cell BAT_{N} through the resistor R_{FN}. The level shifter 216A_{(N-1)} can function as a compensation circuit for the level shifter 216A_{N}, and draws a second current I_{RF2} from the battery cell BAT_{N} through the resistor R_{F(N-1)}. As mentioned above, the bypath circuits 212₁-212_{N} include balance circuits that balance voltages of the battery cells BAT₁-BAT_{N}. Thus, the voltages of the battery cells BAT₁-BAT_{N} can be approximately the same. In an embodiment, the first current I_{RF1} is a function of, e.g., proportional to, a voltage of the battery cell BAT_{N}, and the second current I_{RF2} is a function of, e.g., proportional to, a voltage of the battery cell BAT_{(N-1)}. Accordingly, the currents I_{RF1} and I_{RF2} will be approximately the same when the battery cells BAT_{N} and BAT_{(N-1)} are balanced with each other. Consequently, the control circuit 216C can turn on the level shifter 216A_{(N-1)} when sensing the voltage of the battery cell BAT_{N}, so that the currents I_{RF1} and I_{RF2} flowing through the resistors R_{FN} and R_{F(N-1)} are approximately the same. In an embodiment, the resistors R_{F1}-R_{FN} are selected to have the same resistance, and therefore voltages across the resistors R_{FN} and R_{F(N-1)}, caused by the currents I_{RF1} and I_{RF2}, will be approximately the same because the currents I_{RF1} and I_{RF2} will be approximately the same when the batteries are balanced. In an embodiment, resistances of the resistive components 214₁-214(N−1) are relatively small compared to the resistances of the resistors R_{F1}-R_{FN}. Thus, a voltage across the resistive component 214_{(N-1)}, caused by the second current I_{RF2}, is relatively small and can be ignored. As a result, a voltage V_{N} (e.g., shown in FIG. 2B) received by the controller 216 will reflect the voltage V_{BATN} of the battery cell BAT_{N} more accurately, compared to that received by the conventional battery monitor 114 in FIG. 1. Consequently, the controller 216 can more accurately monitor the voltage of a battery cell and avoid the need for other circuits (e.g., a current source circuit coupled to the negative terminal of the battery cell).

As used herein, “approximately the same” means that a difference may exist among/between parameters (e.g., the voltages of the battery cells BAT₁-BAT_{N}, or the currents I_{RF1} and I_{RF2}) because of, e.g., non-ideality of circuit components, and that the difference is relatively small and can be ignored. As used herein, “the resistors R_{F1}-R_{FN} are selected to have the same resistance” allows differences existing among the resistors R_{F1}-R_{FN} because of non-ideality in practical situation, as long as the differences are relatively small and can be ignored.

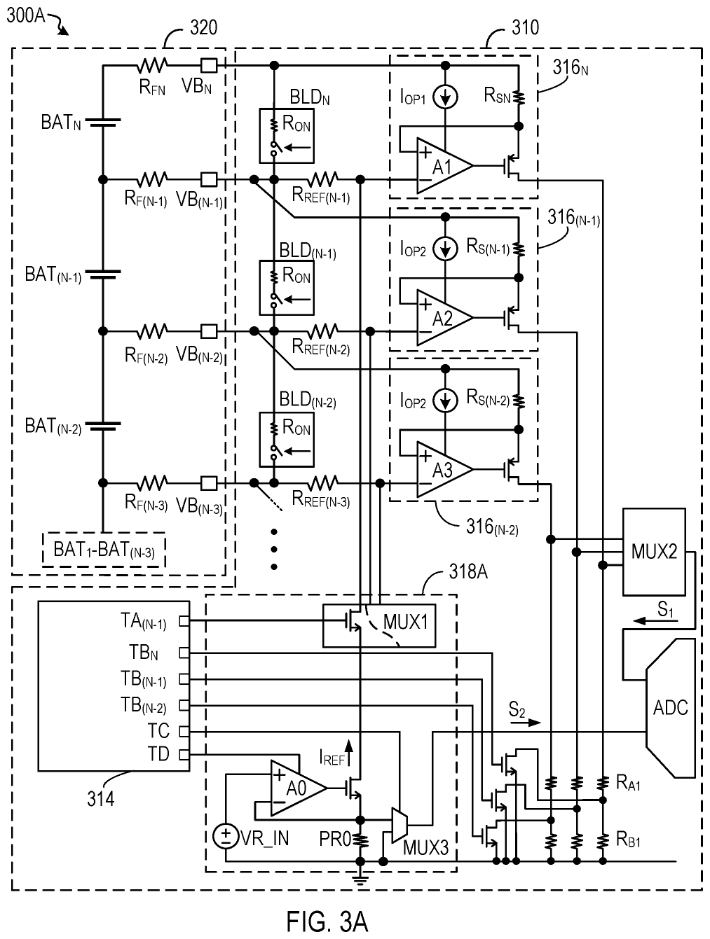

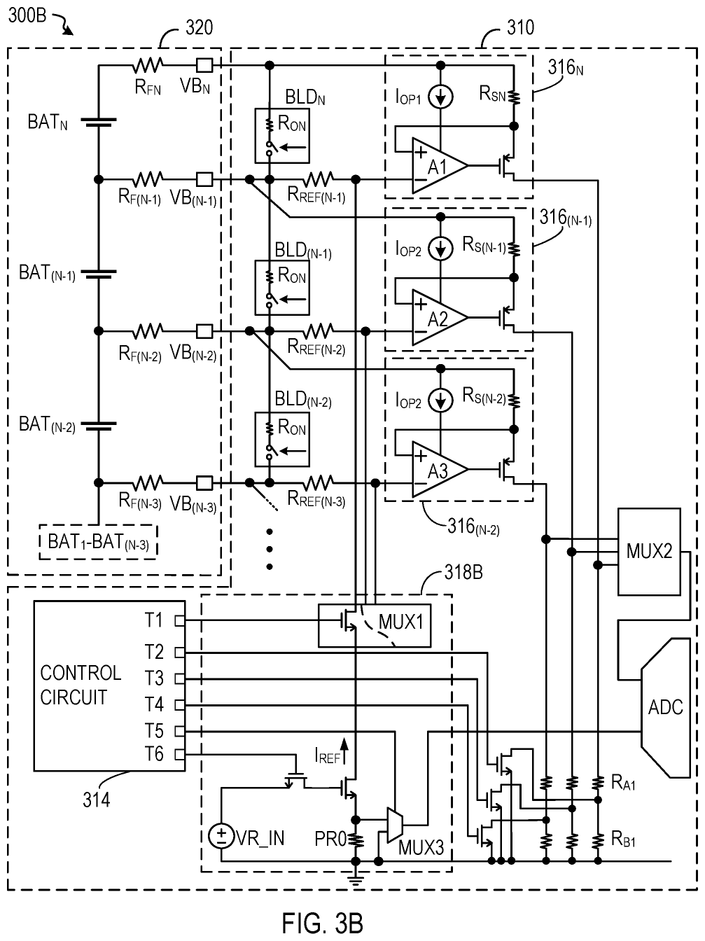

In an embodiment, the control circuit 216C can control turning on and off a selected bypath circuit 212₁ (J=1, 2, . . . , N) and the reference signal source 218, thereby controlling the abovementioned first test voltage V_{TEST1}. If the control circuit 216C turns off the selected bypath circuit 212₁ and the reference signal source 218, then the first test voltage V_{TEST1} can indicate a voltage of a selected battery cell BAT_{J}. A selected level shifter 216A_{J} of the level shifters 216A₁-216A_{N} can convert the first test voltage V_{TEST1} to a sense signal. The monitor 216B can receive the sense signal and monitor the status of the selected battery cell BAT_{J} according to the sense signal. More details are described in combination with the examples of FIG. 3A and FIG. 3B.

FIG. 3A illustrates a circuit diagram of an example of a battery pack 300A, in an embodiment of the present invention. FIG. 3A is described in combination with FIG. 2A and FIG. 2B. As shown in FIG. 3A, the battery pack 300A includes a battery module 320 and a battery monitoring circuit 310. The battery module 320 includes multiple battery cells BAT₁-BAT_{N}. The battery monitoring circuit 310 includes multiple bypath circuits (e.g., including bypath circuits BLD_{N}, BLD_{(N-1)} and BLD_{(N-2)}, and additional bypath circuits not shown in FIG. 3A), multiple resistive components (e.g., including resistive components R_{REF(N-1)}, R_{REF(N-2)} and R_{REF(N-3)}, and additional resistive components not shown in FIG. 3A), and multiple level shifters (e.g., including level shifters 316_{N}, 316_{(N-1)} and 316_{(N-2)}, and additional level shifters not shown in FIG. 3A). The battery monitoring circuit 310 further includes a monitor, a reference signal source 318A, and a control circuit 314.

More specifically, as shown in the example of FIG. 3A, the monitor in the battery monitoring circuit 310 includes a first multiplexer MUX2 and an analog-to-digital converter (ADC). The combined circuit of the multiplexer MUX2 and the converter ADC can be an embodiment of the above-mentioned monitor 216B in FIG. 2B. The reference signal source 318A includes a second multiplexer MUX1, a third multiplexer MUX3, an operational amplifier A0, a voltage source VR_IN, and a resistor PR0. The reference signal source 318A can be an embodiment of the abovementioned reference signal source 218.

In an embodiment, the reference signal source 318A includes a current source, and the reference signal S_{RFN} provided by the reference signal source 318A includes a current I_{REF}. As shown in FIG. 3A, a combined circuit of the voltage source VR_IN, the operational amplifier A0, the resistor PR0, and the transistor coupled to the operational amplifier A0 and the resistor PR0 can be an embodiment of the current source, and can provide a current I_{REF} to the resistive components R_{REF1}-R_{REF(N-1)}.

In an embodiment, the control circuit 314 includes multiple first control terminals (e.g., including a first control terminal TA_{(N-1)}, and additional first control terminals not shown in FIG. 3A), multiple second control terminals (e.g., including second control terminals TB_{N}, TB_{(N-1)}, TB_{(N-2)}, and additional second control terminals not shown in FIG. 3A), a control terminal TC, and a control terminal TD. The control circuit 314 can control the multiplexer MUX1 to transmit the current I_{REF} to a selected resistive component R_{REF(H-1)} (H=2, 3, . . . , N) through a corresponding first control terminal TA_{(H-1)}. For example, if the resistive component R_{REF(N-1)} is the selected resistive component, then the control circuit 314 can control the multiplexer MUX1 to transmit the current I_{REF} to the resistive component R_{REF(N-1)} by enabling the control terminal T_{(N-1)}. The control circuit 314 can also adjust gains of outputs of the level shifters 316₁-316_{N} by controlling the switches coupled to the feedback resistors R_{A1} and R_{B1} through the second control terminals TB₁-TB_{N}. For example, the control circuit 314 can adjust a gain of an output of the level shifter 316_{N} by enabling the control terminal TB_{N}. The control circuit 314 can also turn on or off the reference signal source 318A through the control terminal TD. The control circuit 314 can also enable the multiplexer MUX3 to transmit an output signal (e.g., referred to as a second signal S2 shown in FIG. 3A) of the reference signal source 318A to the converter ADC through the control terminal TC. The control circuit 314 may also include, but not necessarily, control terminals (not shown in the FIG. 3A) for turning on or off the bypath circuits BLD₁-BLD_{N}, control terminals for turning on or off the level shifters 316i-316_{N}, and the like.

More specifically, in an embodiment, the level shifter 316i-316_{N} can sense a voltage signal, e.g., an abovementioned first test voltage V_{TEST1}, second test voltage V_{TEST2}, or third test voltage V_{TEST3}. The level shifter 316i-316_{N} can further send a sense signal, indicative of the voltage signal, to the multiplexer MUX2. The multiplexer MUX2 can generate a first signal S1 according to the sense signal. The multiplexer MUX2 can further send the first signal S1 to the converter ADC. The reference signal source 318A can transmit a second signal S2 to the converter ADC. The second signal S2 can be equal to the abovementioned reference voltage V_{RFN} generated by a resistive component R_{REF1}-R_{REF(N-1)}. The converter ADC can include a differential analog-to-digital converter that converts a difference between the first signal S1 and the second signal S2 to a third signal S3 (not shown in FIG. 3A), and transmits the third signal S3 to the control circuit 314. The control circuit 314 can determine a voltage of a battery cell BAT₁-BAT_{N} according to the third signal S₃.

For example, when sensing a voltage V_{BATN} of the battery cell BAT_{N}, the control circuit 314 can control the reference signal source 318A to be on and the bypath circuit BLD_{N} to be off, then the first signal S1 can represent a value of the voltage of the battery cell BAT_{N} plus the reference voltage V_{RFN}, the second signal S2 can represent a value of the reference voltage V_{RFN}, and the third signal S3 can represent a value of the difference between the first signal S₁ and the second signal S2. If VS₁ represents a voltage indicated by the first signal S₁, VS₂ represents a voltage indicated by the second signal S₂, and VS₃ represents a voltage indicated by the third signal S₃, then VS₁=V_{BATN}+V_{RFN}, VS₂=V_{RFN}, and VS₃=VS₁−VS₂. Accordingly, the voltage V_{BATN} of the battery cell BAT_{N} can be given by: V_{BATN}=VS₃.

In an embodiment, the control circuit 314 can pre-store a fourth signal S₄ (not shown in FIG. 3A). The fourth signal S₄ can be controlled to be equal to a value of the reference voltage V_{RFN}. The control circuit 314 can perform a self-test function (e.g., testing whether the reference resistors R_{REF1}-R_{REF(N-1)} operate properly) according to the third signal S₃ and the fourth signal S₄. For example, when testing the reference resistor R_{REF(N-1)}, the control circuit 314 can control the reference signal source 318A and the bypath circuit BLD_{N} to be on, and control the multiplexer MUX3 to be off, then the value of the second signal S₂ can be equal to or approximately equal to 0V. Accordingly, the value of the third signal S₃ is equal to or approximately equal to the value of the fourth signal S₄ if the reference resistor R_{REF(N-1)} operates properly. If the value of the third signal S₃ is different from the value of the fourth signal S₄, it can indicate an abnormal condition present in the reference resistor R_{REF(N-1)}. Consequently, the control circuit 314 can test whether the reference resistor R_{REF(N-1)} operates properly by comparing the value of the third signal S₃ with the value of the fourth signal S₄.

In an embodiment, resistances of the resistors R_{F1}-R_{FN} may be relatively small compared to resistances of the bypath circuits BLD₁-BLD_{N}, such that voltages generated by the bypath circuits BLD₁-BLD_{N} are large enough to be sensed. In this embodiment, the control circuit 314 can sense a reference voltage V_{RFN} generated by a resistive component R_{REF(H-1)}. More specifically, the control circuit 314 can sense a first voltage V₁ (e.g., similar to an abovementioned second test voltage V_{TEST2}) from a bypath circuit BLD_{H} through a level shifter 316_{H} when the reference signal source 318A is off and the bypath circuit BLD_{H} is on. The control circuit 314 can further sense a second voltage V₂ (e.g., similar to an abovementioned first test voltage V_{TEST1}) from the bypath circuit BLD_{H} through the level shifter 316_{H} when the reference signal source 318A and the bypath circuit BLD_{H} are on, where the corresponding first control terminal TA_{(H-1)} is enabled so that the current I_{REF} can be transmitted to the resistive component R_{REF(H-1)}. Then, the control circuit 314 can calculate the reference voltage V_{RFN} generated by the resistive component R_{REF(H-1)}, e.g., the reference voltage V_{RFN} can be given by: V_{RFN}=V₂-V₁.

As shown in FIG. 3A, the bypath circuit BLD₁-BLD_{N} includes a resistor RON and a switch which can be controlled by the control circuit 314. Thus, the bypath circuit BLD₁-BLD_{N} can have a resistance represented by RON when the bypath circuit BLD₁-BLD_{N} is turned on. The bypath circuit BLD₁-BLD_{N} can be an embodiment of the abovementioned bypath circuit 212₁-212_{N}. The level shifter 316₁-316_{N} may include an operational amplifier, a current source, a resistor, and a transistor. The level shifter 316₁-316_{N} can be an embodiment of the level shifter 216₁-216_{N} in FIG. 2B.

In another embodiment, resistances of the resistors R_{F1}-R_{FN} may be relatively large compared to resistances of the bypath circuits BLD₁-BLD_{N}, such that voltages generated by the bypath circuits BLD₁-BLD_{N} are relatively small and can be ignored. In this embodiment, the control circuit 314 can sense a third voltage V₃ (e.g., similar to an abovementioned first test voltage V_{TEST1}) through the level shifter 316_{H} when the bypath circuit BLD_{H} and the reference signal source 318A are on. The control circuit 314 can further determine whether the reference signal source 318A is functioning normally according to the third voltage V₃ and a pre-defined voltage. For example, the pre-defined voltage can be equal to or approximately equal to the abovementioned reference voltage V_{RFN}. If the third voltage V₃ is equal to or approximately equal to the pre-defined voltage, then the control circuit 314 can determine that the reference signal source 318A is functioning normally.

The present invention further provides another embodiment of the reference signal source 218. FIG. 3B illustrates a circuit diagram of an example of a battery pack 300B, in an embodiment of the present invention. FIG. 3B is described in combination with FIG. 2A, FIG. 2B, and FIG. 3A. As shown in FIG. 3B, the battery pack 300B includes a reference signal source 318B. The reference signal source 318B includes a second multiplexer MUX1, a third multiplexer MUX3, two transistors, a voltage source VR_IN, and a resistor PR0. The reference signal source 318B can be an embodiment of the abovementioned reference signal source 218.

In an embodiment, the reference signal source 318B includes a current source, and the reference signal S_{RFN} provided by the reference signal source 318A includes a current I_{REF}. As shown in FIG. 3B, a combined circuit of the voltage source VR_IN, the resistor PR0, and the transistors coupled to the voltage source VR_IN and the resistor PR0 can be an embodiment of the current source, and can provide a current I_{REF} to the resistive components R_{REF1}-R_{REF(N-1)}.

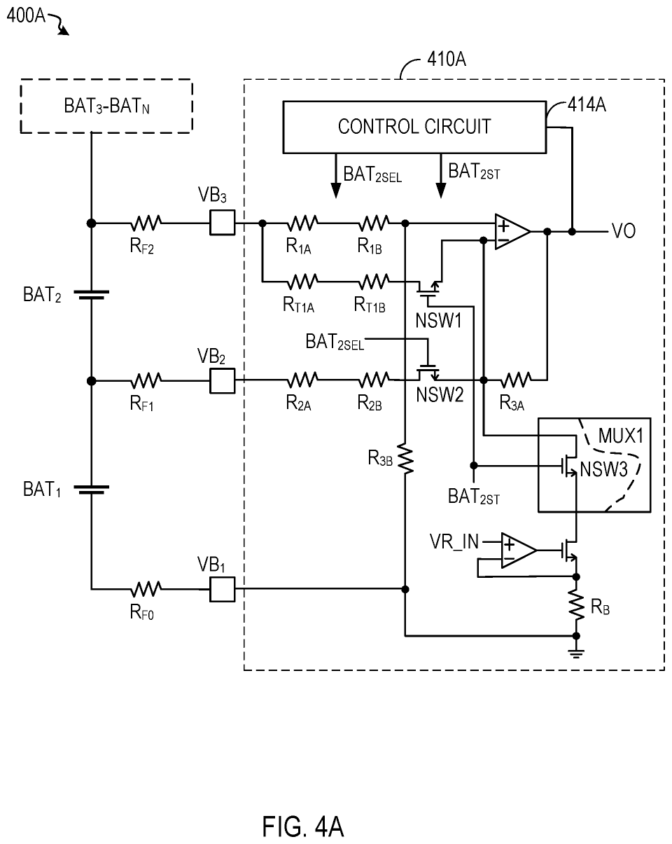

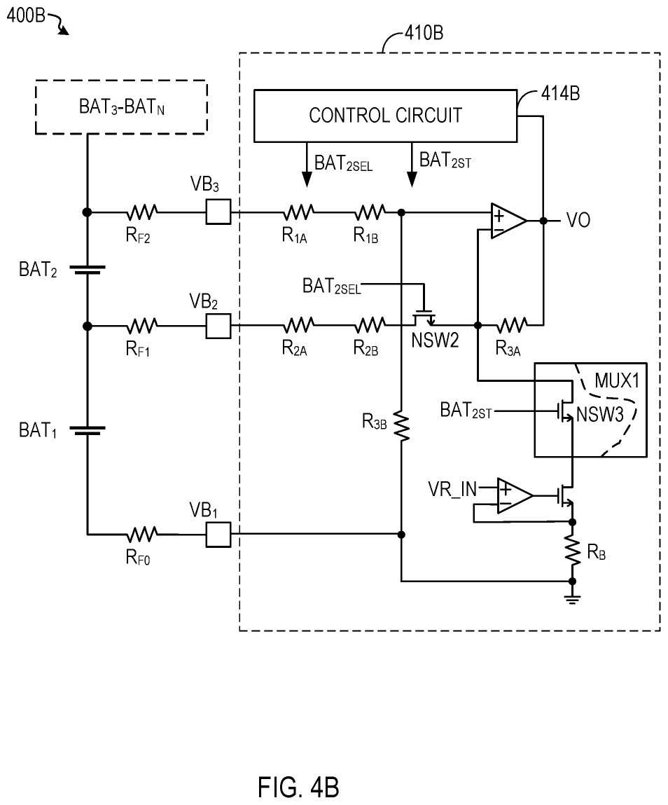

In the examples of FIG. 2A, FIG. 2B, FIG. 3A, and FIG. 3B, the battery cells BAT₁-BAT_{N} are connected in series, and circuitry for monitoring the battery cells BAT₁ and BAT₂ are not shown in FIG. 2A, FIG. 2B, FIG. 3A, and FIG. 3B. Examples of the circuitry for monitoring the battery cells is BAT₁ and BAT₂ are described in FIG. 4A and FIG. 4B.

FIG. 4A illustrates a circuit diagram of an example of a battery pack 400A, in an embodiment of the present invention. As shown in FIG. 4A, the battery pack 400A includes battery cells BAT₁-BAT_{N} and a battery monitoring circuit 410A. The battery monitoring circuit 410A can include a control circuit 414A. The control circuit 414A can monitor statuses of the battery cells BAT₁ and BAT₂ and monitors operation statuses of the battery monitoring circuit 410A according to voltages of a terminal VO. In an embodiment, the abovementioned control circuit 314 can include the control circuit 414A. FIG. 4A is described in combination with FIG. 2A, FIG. 2B, FIG. 3A, and FIG. 3B.

More specifically, in the example of FIG. 4A, the battery monitoring circuit 410A includes switches NSW1 and NSW2, and includes a multiplexer MUX1 having a switch NSW3. The control circuit 414A can selectively turn on or off the switches NSW1, NSW2, and NSW3 through control terminals BAT_{2SEL} and BAT_{2ST}. The battery monitoring circuit 410A also includes resistors R_{1A}, R_{1B}, R_{2A}, R_{2B}, R_{T1A}, R_{T1B}, R_{3A}, R_{3B}, and RB. In an embodiment, by selecting appropriate resistance values for the resistors R_{1A}, R_{1B}, R_{2A}, R_{2B}, R_{3A}, and R_{3B}, an output signal Vo at the terminal VO can represent a voltage V_{BAT2} of the battery cell BAT₂ when the switches NSW1 and NSW3 are off and the switch NSW2 is on. For example, if the resistors R_{1A}, R_{1B}, R_{2A}, R_{2B}, R_{3A}, and R_{3B} have the same resistance, then the output signal Vo can be equal to (½)*V_{BAT2}. Thus, the battery monitoring circuit 410A can monitor a voltage V_{BAT2} of the battery cell BAT₂. As to the battery cell BAT₁, the battery monitoring circuit 410A can monitor a voltage of the battery cell BAT₁ through a feedback circuit (not shown), e.g., similar to the voltage divider including feedback resistors R_{A1} and R_{B1} shown in FIG. 3A.

Additionally, in an embodiment, by selecting appropriate resistance values for the resistors R_{T1A}, R_{T1B} and R_{B}, the battery monitoring circuit 410A can perform a self-test function to determine whether a fault is present in the battery pack 400A. By way of example, the control circuit 414A can sense a voltage VOₜ₁ through the terminal VO when the switch NSW2 is on and the switches NSW1 and NSW3 are off. The control circuit 414A can sense a voltage VOₜ₂ through the terminal VO when the switches NSW1, NSW2, and NSW3 are on. Then, the control circuit 414A can determine an operating status of the battery monitoring circuit 410A based on a difference between the voltage VOₜ₂ and the voltage VOₜ₁. For example, if the resistors R_{T1A}, R_{T1B} and R_{B} and the resistors R_{1A}, R_{1B}, R_{2A}, R_{2B}, R_{3A}, and R_{3B} have the same resistance, then the difference between the voltage VOₜ₁ and the voltage VOₜ₂ can be equal to a reference voltage VR provided by a voltage source VR_IN (e.g., VOₜ₂−VOₜ₁=VR) when the battery cells BAT₁-BAT_{N} and the battery monitoring circuit 410A are working normally. Accordingly, in an embodiment, if the control circuit 414A detects that the voltage difference VOₜ₂−VOₜ₁ is approximately equal to the reference voltage VR, then it can be determined that no fault is detected; otherwise, it is determined that a fault is present in the battery pack 400A.

FIG. 4B illustrates a circuit diagram of an example of a battery pack 400B, in another embodiment of the present invention. The battery pack 400B differs from the battery pack 400A in that the resistor R_{T1A}, the resistor R_{T1B} and the transistor NSW1 in the battery pack 400A are omitted in the battery pack 400B. As a result, compared with the battery pack 400A, the battery pack 400B can occupy a smaller printed circuit board and can cost less. FIG. 4B is described in combination with FIG. 2A, FIG. 2B, FIG. 3A, FIG. 3B, and FIG. 4A.

As shown in FIG. 4B, the battery pack 400B includes battery cells BAT₁-BAT_{N} and a battery monitoring circuit 410B. The battery monitoring circuit 410B includes a control circuit 414B. Similar to the control circuit 414A in FIG. 4A, the control circuit 414B can monitor statuses, e.g., voltages, of the battery cells BAT₁ and BAT₂. The control circuit 414B can also monitor operation statuses of the battery monitoring circuit 410B according to voltages of a terminal VO. In an embodiment, the abovementioned control circuit 314 can include the control circuit 414B.

More specifically, in an embodiment, the control circuit 414B can sense a voltage VOₜ₁ through the terminal VO when the transistor NSW2 is on and the transistor NSW3 is off. The control circuit 414B can sense a voltage VOₜ₂ through the terminal VO when the transistors NSW2 and NSW3 are on. Then, the control circuit 414B can determine an operating status of the battery monitoring circuit 410B based on a difference between the voltages VOₜ₂ and VOₜ₁. For example, if the resistors R_{1A}, RIB, R_{2A}, R_{2B}, R_{3A}, R_{3B}, and R_{B} are selected to have the same resistance, then a difference between the voltage VOₜ₁ and the voltage VOU can be equal to a reference voltage VR provided by a voltage source VR_IN (e.g., VOₜ₂−VOₜ₁=VR) if circuitry in the battery pack 400B is working normally. Thus, similarly to the control circuit 414A in FIG. 4A, the control circuit 414B can determine whether a fault is present in the battery pack 400B by comparing the voltage difference VOₜ₂−VOₜ₁ with the reference voltage VR.

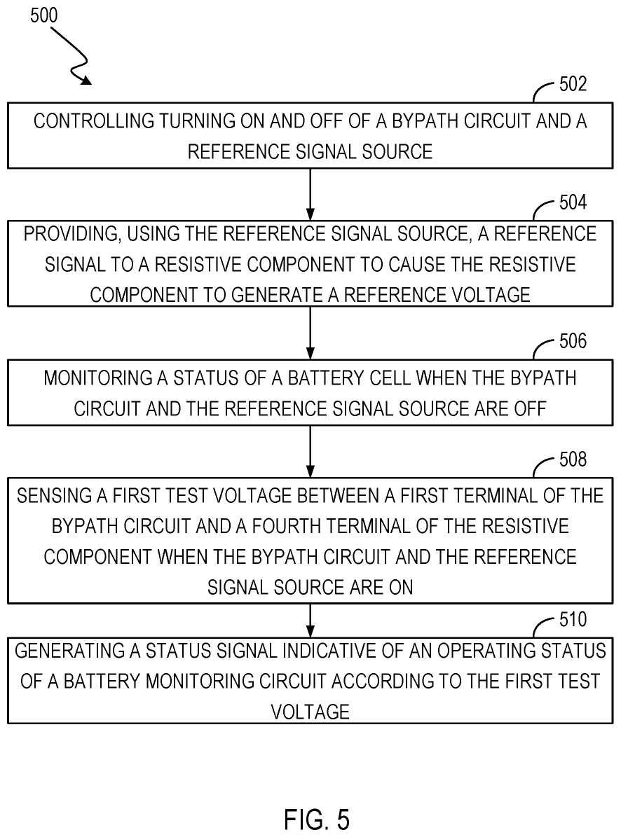

FIG. 5 illustrates a flowchart 500 of an example of a method for monitoring a battery, in an embodiment of the present invention. Although specific steps are disclosed in FIG. 5, such steps are examples for illustrative purposes. In this way, embodiments according to the present invention are well suited to performing various other steps or variations of the steps recited in FIG. 5. FIG. 5 is described in combination with FIG. 2A, FIG. 2B, FIG. 3A, FIG. 3B, FIG. 4A, and FIG. 4B.

At step 502, the controller 216 controls turning on and off the bypath circuit 212_{N} and the reference signal source 218.

At step 504, the controller 216 provides, using the reference signal source 218, a reference signal, e.g., I_{REF}, to the resistive component 214_{(N-1)} to cause the resistive component 214_{(N-1)} to generate a reference voltage, e.g., V_{RFN}.

At step 506, the controller 216 monitors a status of the battery cell BAT_{N} when the bypath circuit 212_{N} and the reference signal source 218 are off.

At step 508, the controller 216 senses a first test voltage V_{TEST1} between the first terminal 211A of the bypath circuit 212_{N} and the fourth terminal 213B of the resistive component 214_{(N-1)} when the bypath circuit 212_{N} and the reference signal source 218 are on.

At step 510, the controller 216 generates a status signal indicative of an operating status of the battery monitoring circuit 210 according to the first test voltage V_{TEST1}.

While the foregoing description and drawings represent embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

We claim:

1. A battery monitoring circuit comprising:
a bypath circuit comprising a first terminal coupled to a positive terminal of a battery cell, and comprising a second terminal coupled to a negative terminal of said battery cell;
a resistive component comprising a third terminal and a fourth terminal, wherein said third terminal is coupled to said second terminal;
a reference signal source, coupled to said fourth terminal, and configured to provide a reference signal to said resistive component to cause said resistive component to generate a reference voltage; and
a controller, coupled to said bypath circuit, said resistive component, and said reference signal source, configured to control turning on and off said bypath circuit and said reference signal source, and configured to monitor a status of said battery cell when said bypath circuit and said reference signal source are off,
wherein said controller is further configured to sense a first test voltage between said first terminal of said bypath circuit and said fourth terminal of said resistive component when said bypath circuit and said reference signal source are on, and is further configured to generate a status signal indicative of an operating status of said battery monitoring circuit according to said first test voltage.

2. The battery monitoring circuit of claim 1, wherein said bypath circuit comprises a balance circuit configured to balance a voltage of said battery cell with voltages of a set of battery cells coupled to said battery cell.

3. The battery monitoring circuit of claim 1, wherein said reference signal source comprises a current source, and said reference signal provided by said reference signal source comprises a current.

4. The battery monitoring circuit of claim 1, wherein said controller is configured to generate a monitoring circuit fault signal, comprised in said status signal, if said first test voltage is outside a safe range determined by said reference voltage, and wherein said monitoring circuit fault signal is indicative of a fault in said battery monitoring circuit.

5. The battery monitoring circuit of claim 1, wherein said controller is configured to sense a second test voltage between said first terminal and said fourth terminal when said bypath circuit is on and said reference signal source is off, configured to sense a third test voltage between said first terminal and said fourth terminal when said bypath circuit and said reference signal source are off, and configured to generate a battery fault signal, comprised in said status signal, indicative of a fault in said battery cell if said second test voltage and said third test voltage are less than a preset level.

6. The battery monitoring circuit of claim 1, wherein said controller is configured to sense a second test voltage between said first terminal and said fourth terminal when said bypath circuit is off and said reference signal source is on, and configured to determine a voltage of said battery cell according to a difference between said second test voltage and said reference voltage if said voltage of said battery cell is less than a preset value.

7. The battery monitoring circuit of claim 1, wherein said controller comprises:
a first level shifter comprising a first monitoring terminal coupled to said positive terminal through a first resistive component, and also comprising a second monitoring terminal coupled to said negative terminal through a second resistive component, and configured to sense a voltage of said battery cell by receiving a first current from said battery cell through said first resistive component; and
a compensation circuit coupled to said negative terminal through said second resistive component, and configured to draw a second current from said battery cell through said second resistive component.

8. The battery monitoring circuit of claim 7, wherein said compensation circuit comprises a second level shifter configured to sense a voltage of an adjacent battery cell coupled in series to said battery cell by receiving a current from said adjacent battery cell through said second resistive component.

9. A battery pack comprising:
a plurality of battery cells; and
a battery monitoring circuit, coupled to said battery cells, and configured to monitor said battery cells, said battery monitoring circuit comprising:
a plurality of bypath circuits coupled to said battery cells, wherein each bypath circuit of said bypath circuits comprises: a respective first terminal coupled to a positive terminal of a corresponding battery cell of said battery cells, and a respective second terminal coupled to a negative terminal of said corresponding battery cell;
a plurality of resistive components coupled to said bypath paths, wherein each resistive component of said resistive components comprises: a respective third terminal coupled to the second terminal of a corresponding bypath circuit of said bypath paths, and a respective fourth terminal;
a reference signal source, coupled to said respective fourth terminal of said each resistive component, and configured to provide a reference signal to a selected resistive component of said resistive components to cause said selected resistive component to generate a reference voltage; and
a controller, coupled to said bypath circuits, said resistive components, and said reference signal source, and configured to control turning on and off said bypath circuits and said reference signal source, and further configured to monitor a status of a selected battery cell of said battery cells when a selected bypath circuit of said bypath paths, coupled to said selected battery cell, and said reference signal source are off,
wherein said controller is further configured to sense a first test voltage between the first terminal of said selected bypath circuit and the fourth terminal of said selected resistive component when said selected bypath circuit and said reference signal source are on, and further configured to generate a status signal indicative of an operating status of said battery monitoring circuit according to said first test voltage, and wherein said selected resistive component is coupled to said selected bypath circuit.

10. The battery pack of claim 9, wherein said controller is configured to generate a monitoring circuit fault signal, comprised in said status signal, if said first test voltage is outside a safe range determined by said reference voltage, and wherein said monitoring circuit fault signal is indicative of a fault in said battery monitoring circuit.

11. The battery pack of claim 9, wherein said controller is configured to sense a second test voltage between the first terminal of said selected bypath circuit and the fourth terminal of said selected resistive component when said selected bypath circuit is on and said reference signal source is off, configured to sense a third test voltage between the first terminal of said selected bypath circuit and the fourth terminal of said selected resistive component when said selected bypath circuit and said reference signal source are off, and configured to generate a battery fault signal, comprised in said status signal, indicative of a fault in said selected battery cell if said second test voltage and said third test voltage are less than a preset level.

12. The battery pack of claim 9, wherein said controller is configured to sense a second test voltage between the first terminal of said selected bypath circuit and the fourth terminal of said selected resistive component when said selected bypath circuit is off and said reference signal source is on, and configured to determine a voltage of said selected battery cell according to a difference between said second test voltage and said reference voltage generated by said selected resistive component if said voltage of said selected battery cell is less than a preset value.

13. The battery pack of claim 9, wherein said controller comprises:
a first level shifter comprising a first monitoring terminal coupled to the positive terminal of said selected battery cell through a first resistive component, and also comprising a second monitoring terminal coupled to the negative terminal of said selected battery cell through a second resistive component, and configured to sense a voltage of said selected battery cell by receiving a first current from said selected battery cell through said first resistive component; and
a compensation circuit coupled to the negative terminal of said selected battery cell through said second resistive component, and configured to draw a second current from said selected battery cell through said second resistive component.

14. The battery pack of claim 13, wherein said compensation circuit comprises a second level shifter configured to sense a voltage of an adjacent battery cell coupled in series to said selected battery cell by receiving a current from said adjacent battery cell through said second resistive component.

15. The battery pack of claim 9, wherein said selected bypath circuit comprises a balance circuit configured to balance a voltage of said selected battery cell with voltages of a set of battery cells coupled to said selected battery cell.

16. A method for monitoring a battery, said method comprising:
controlling turning on and off a bypath circuit and a reference signal source of a battery monitoring circuit, wherein said bypath circuit comprises a first terminal coupled to a positive terminal of a battery cell, and comprises a second terminal coupled to a negative terminal of said battery cell;
providing, using said reference signal source, a reference signal to a resistive component of said battery monitoring circuit, to cause said resistive component to generate a reference voltage, wherein said resistive component comprises a third terminal and a fourth terminal, wherein said third terminal is coupled to said second terminal of said bypath circuit, and wherein said fourth terminal is coupled to said reference signal source;
monitoring a status of said battery cell when said bypath circuit and said reference signal source are off,
sensing a first test voltage between said first terminal and said fourth terminal when said bypath circuit and said reference signal source are on; and
generating a status signal indicative of an operating status of said battery monitoring circuit according to said first test voltage.

17. The method of claim 16, wherein said status signal comprises a monitoring circuit fault signal indicative of a fault in said battery monitoring circuit, and wherein said method further comprises:
generating said monitoring circuit fault signal if said first test voltage is outside a safe range determined by said reference voltage.

18. The method of claim 16, wherein said status signal comprises a battery fault signal indicative of a fault in said battery cell, and wherein said method further comprises:
sensing a second test voltage between said first terminal and said fourth terminal when said bypath circuit is on and said reference signal source is off,
sensing a third test voltage between said first terminal and said fourth terminal when said bypath circuit and said reference signal source are off, and
generating said battery fault signal if said second test voltage and said third test voltage are less than a preset level.

19. The method of claim 16, further comprising:
sensing a second test voltage between said first terminal and said fourth terminal when said bypath circuit is off and said reference signal source is on; and
determining a voltage of said battery cell according to a difference between said second test voltage and said reference voltage if said voltage of said battery cell is less than a preset value.

20. The method of claim 16, further comprising:
sensing, using a first level shifter, a voltage of said battery cell by receiving a first current from said battery cell through a first resistive component, wherein said first level shifter comprises a first monitoring terminal coupled to said positive terminal of said battery through said first resistive component, and also comprises a second monitoring terminal coupled to said negative terminal of said battery cell through a second resistive component; and
drawing, using a compensation circuit, a second current from said battery cell through said second resistive component, wherein said compensation circuit is coupled to said negative terminal of said battery cell through said second resistive component.
